(19) United States
(12) Patent Application Publication
(10) Pub. No.: US 2015/0129996 A1
(43) Pub. Date: May 14, 2015

(54) METHOD AND SYSTEM FOR PROVIDING A TOP PINNED LAYER PERPENDICULAR MAGNETIC ANISOTROPY MAGNETIC JUNCTION USABLE IN SPIN TRANSFER TORQUE MAGNETIC RANDOM ACCESS MEMORY APPLICATIONS

(71) Applicant: Samsung Electronics Co., LTD., Gyeonggi-do (KR)

(72) Inventors: Xueti Tang, San Jose, CA (US); Jang Eun Lee, Cupertino, CA (US); Kiseok Moon, Pleasanton, CA (US)

(73) Assignee: Samsung Electronics Co., LTD., Gyeonggi-do (KR)

(21) Appl. No.: 14/184,664

(22) Filed: Feb. 19, 2014

Related U.S. Application Data
(60) Provisional application No. 61/902,863, filed on Nov. 12, 2013.

(51) Int. Cl. H01L 43/12; H01L 43/02; H01L 27/22; H01L 43/08

(52) U.S. Cl. CPC H01L 43/12; H01L 43/08; H01L 43/02; H01L 27/222
USPC 257/427; 438/3; 257/421

(57) ABSTRACT

A method for providing a magnetic junction usable in a magnetic device and the magnetic junction are described. A free layer and nonmagnetic spacer layer are provided. The free layer and nonmagnetic spacer layer are annealed at an anneal temperature of at least three hundred fifty degrees Celsius. A pinned layer is provided after the annealing step. The nonmagnetic spacer layer is between the pinned layer and the free layer. The magnetic junction is configured such that the free layer is switchable between a plurality of stable magnetic states when a write current is passed through the magnetic junction.

### CROSS-REFERENCE TO RELATED APPLICATIONS

This application claims the benefit of provisional Patent Application Ser. No. 61/902,863, filed Nov. 12, 2013, entitled TOP PINNED LAYER PERPENDICULAR MAGNETIC ANISOTROPY FREE LAYER MAGNETIC JUNCTION USABLE IN SPIN TRANSFER TORQUE MAGNETIC RANDOM ACCESS MEMORY APPLICATIONS, assigned to the assignee of the present application, and incorporated herein by reference.

### BACKGROUND OF THE INVENTION

Magnetic memories, particularly magnetic random access memories (MRAMs), have drawn increasing interest due to their potential for high read/write speed, excellent endurance, non-volatility and low power consumption during operation. An MRAM can store information utilizing magnetic materials as an information recording medium. One type of MRAM is a spin transfer torque random access memory (STT-MRAM). STT-MRAM utilizes magnetic junctions written at least in part by a current driven through the magnetic junction. A spin polarized current driven through the magnetic junction exerts a spin torque on the magnetic moments in the magnetic junction. As a result, layer(s) having magnetic moments that are responsive to the spin torque may be switched to a desired state.

For example, FIG. 1 depicts a conventional magnetic tunneling junction (MTJ) 10 as it may be used in a conventional STT-MRAM. The conventional MTJ 10 typically resides on a substrate 12. A bottom contact 14 and top contact 24 may be used to drive current through the conventional MTJ 10. The conventional MTJ, uses conventional seed layer(s) (not shown), may include capping layers (not shown) and may include a conventional antiferromagnetic (AFM) layer (not shown). The conventional magnetic junction 10 includes a conventional pinned layer 16, a conventional tunneling barrier layer 18, and a conventional free layer 20. Also shown is top contact 22. Conventional contacts 14 and 24 are used in driving the current in a current-perpendicular-to-plane (CPP) direction, or along the z-axis as shown in FIG. 1. Typically, the conventional pinned layer 16 is closest to the substrate 12 of the layers 16, 18 and 20.

The conventional pinned layer 16 and the conventional free layer 20 are magnetic. The magnetization 17 of the conventional pinned layer 16 is fixed, or pinned, in a particular direction. Although depicted as a simple (single) layer, the conventional pinned layer 16 may include multiple layers. For example, the conventional pinned layer 16 may be a synthetic antiferromagnetic (SAF) layer including magnetic layers antiferromagnetically coupled through thin conductive layers, such as Ru. In such a SAF, multiple magnetic layers interleaved with a thin layer of Ru may be used. In another embodiment, the coupling across the Ru layers can be ferromagnetic.

The conventional free layer 20 has a changeable magnetization 21. Although depicted as a simple layer, the conventional free layer 20 may also include multiple layers. For example, the conventional free layer 20 may be a synthetic layer including magnetic layers antiferromagnetically or ferromagnetically coupled through thin conductive layers, such as Ru. Although shown as perpendicular-to-plane, the magnetization 21 of the conventional free layer 20 may be in plane. Thus, the pinned layer 16 and free layer 20 may have their magnetizations 17 and 21, respectively oriented perpendicular to the plane of the layers.

To fabricate the conventional magnetic junction 10, the layers 16, 18 and 20 are deposited. After the layer 16, 18 and 20 has been provided, the magnetic junction 10 is annealed. This annealing assists in the crystallization of the conventional tunneling barrier 18, which may be amorphous as-deposited. The layers for the conventional magnetic junction 10 are then milled to define the edges of the conventional magnetic junction 10.

To switch the magnetization 21 of the conventional free layer 20, a current is driven perpendicular to plane (in the z-direction). When a sufficient current is driven from the top contact 22 to the bottom contact 14, the magnetization 21 of the conventional free layer 20 may switch to be parallel to the magnetization 17 of the conventional pinned layer 16. When a sufficient current is driven from the bottom contact 11 to the top contact 22, the magnetization 21 of the free layer may switch to be antiparallel to that of the pinned layer 16. The differences in magnetic configurations correspond to different magnetoresistances and thus different logical states (e.g. a logical “0” and a logical “1”) of the conventional MTJ 10.

Because of their potential for use in a variety of applications, research in magnetic memories is ongoing. For example, mechanisms for improving the performance of STT-RAM are desired. Accordingly, what is needed is a method and system that may improve the performance of the spin transfer torque based memories. The method and system described herein address such a need.

### BRIEF SUMMARY OF THE INVENTION

A method for providing a magnetic junction usable in a magnetic device and the magnetic junction are described. A free layer and nonmagnetic spacer layer are provided. The free layer and nonmagnetic spacer layer are annealed at an anneal temperature of at least three hundred fifty degrees Celsius. A pinned layer is provided after the annealing step. The nonmagnetic spacer layer is between the pinned layer and the free layer. The magnetic junction is configured such that the free layer is switchable between a plurality of stable magnetic states when a write current is passed through the magnetic junction.

### BRIEF DESCRIPTION OF SEVERAL VIEWS OF THE DRAWINGS

FIG. 1 depicts a conventional magnetic junction.

FIG. 2 depicts an exemplary embodiment of a method for providing a magnetic junction usable in a magnetic memory and programmable using spin transfer torque.

FIG. 3 depicts an exemplary embodiment of a magnetic junction usable in a magnetic memory programmable using spin transfer torque.

FIG. 4 depicts another exemplary embodiment of a method for providing a magnetic junction usable in a magnetic memory and programmable using spin transfer torque.

FIG. 5 depicts another exemplary embodiment of a method for providing a magnetic junction usable in a magnetic memory and programmable using spin transfer torque.

FIG. 6 depicts an exemplary embodiment of a magnetic junction usable in a magnetic memory programmable using spin transfer torque.

FIG. 7 depicts another exemplary embodiment of a method for providing a magnetic junction usable in a magnetic memory and programmable using spin transfer torque.

FIG. 8 depicts an exemplary embodiment of a magnetic junction usable in a magnetic memory programmable using spin transfer torque.

FIG. 9 depicts another exemplary embodiment of a method for providing a magnetic junction usable in a magnetic memory and programmable using spin transfer torque.

FIG. 10 depicts an exemplary embodiment of a magnetic junction usable in a magnetic memory programmable using spin transfer torque.

FIG. 11 depicts an exemplary embodiment of a magnetic junction usable in a magnetic memory programmable using spin transfer torque.

FIG. 12 depicts an exemplary embodiment of a magnetic junction usable in a magnetic memory programmable using spin transfer torque.

FIG. 13 depicts an exemplary embodiment of a magnetic junction usable in a magnetic memory programmable using spin transfer torque.

FIG. 14 depicts an exemplary embodiment of a magnetic junction usable in a magnetic memory programmable using spin transfer torque.

FIG. 15 depicts an exemplary embodiment of a memory utilizing magnetic junctions in the memory element(s) of the storage cell(s).

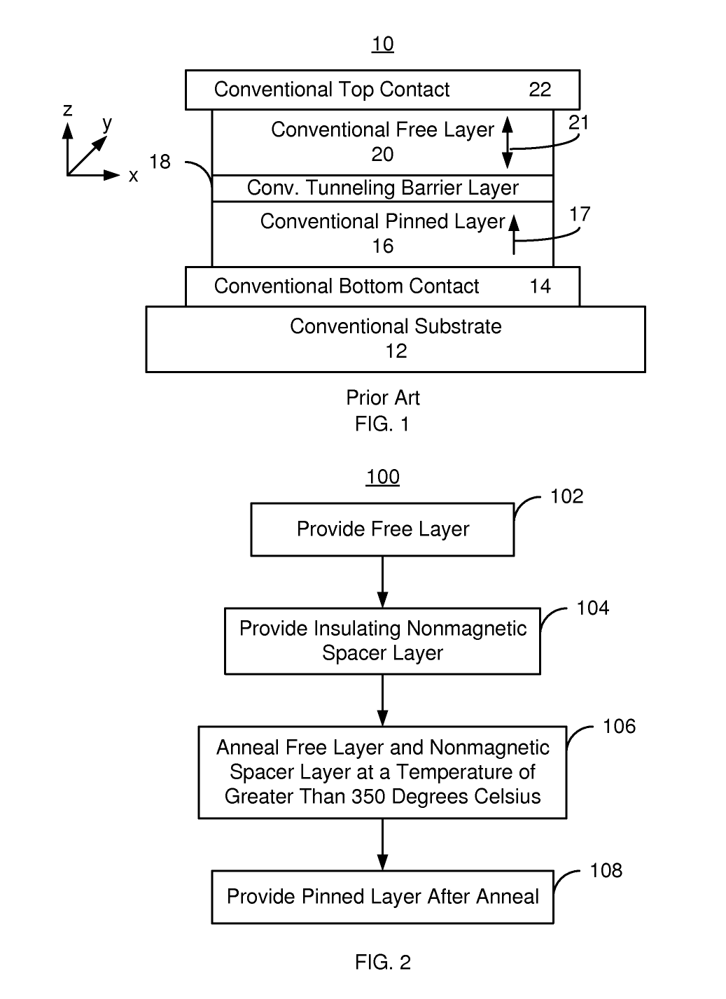

### DETAILED DESCRIPTION OF THE INVENTION

The exemplary embodiments relate to magnetic junctions usable in magnetic devices, such as magnetic memories, and the devices using such magnetic junctions. The magnetic memories may include spin transfer torque magnetic random access memories (STT-MRAMs) and may be used in electronic devices employing nonvolatile memory. Such electronic devices include but are not limited to cellular phones, smart phones, tables, laptops and other portable and non-portable computing devices. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or less components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein.

Methods and systems for providing a magnetic junction as well as a magnetic memory utilizing the magnetic junction are described. The exemplary embodiments provide a method for providing a magnetic junction usable in a magnetic device and the magnetic junction. A free layer and nonmagnetic spacer layer are provided. The free layer and nonmagnetic spacer layer are annealed at an anneal temperature of at least three hundred fifty degrees Celsius. A pinned layer is provided after the annealing step. The nonmagnetic spacer layer is between the pinned layer and the free layer. The magnetic junction is configured such that the free layer is switchable between a plurality of stable magnetic states when a write current is passed through the magnetic junction.

The exemplary embodiments are described in the context of particular methods, magnetic junctions and magnetic memories having certain components. One of ordinary skill in the art will readily recognize that the present invention is consistent with the use of magnetic junctions and magnetic memories having other and/or additional components and/or other features not inconsistent with the present invention. The method and system are also described in the context of current understanding of the spin transfer phenomenon, of magnetic anisotropy, and other physical phenomenon. Consequently, one of ordinary skill in the art will readily recognize that theoretical explanations of the behavior of the method and system are made based upon this current understanding of spin transfer, magnetic anisotropy and other physical phenomena. However, the method and system described herein are not dependent upon a particular physical explanation. One of ordinary skill in the art will also readily recognize that the method and system are described in the context of a structure having a particular relationship to the substrate. However, one of ordinary skill in the art will readily recognize that the method and system are consistent with other structures. In addition, the method and system are described in the context of certain layers being synthetic and/or simple. However, one of ordinary skill in the art will readily recognize that the layers could have another structure. Furthermore, the method and system are described in the context of magnetic junctions and/or substructures having particular layers. However, one of ordinary skill in the art will readily recognize that magnetic junctions and/or substructures having additional and/or different layers not inconsistent with the method and system could also be used. Moreover, certain components are described as being magnetic, ferromagnetic, and ferrimagnetic. As used herein, the term magnetic could include ferromagnetic, ferrimagnetic or like structures. Thus, as used herein, the term “magnetic” or “ferromagnetic” includes, but is not limited to ferromagnets and ferrimagnets. As used herein, “in-plane” is substantially within or parallel to the plane of one or more of the layers of a magnetic junction. Conversely, “perpendicular” and “perpendicular-to-plane” corresponds to a direction that is substantially perpendicular to one or more of the layers of the magnetic junction.

FIG. 2 depicts an exemplary embodiment of a method 100 for fabricating a magnetic junction usable in a magnetic device such as a spin transfer torque random access memory (STT-RAM) and, therefore, in a variety of electronic devices. For simplicity, some steps may be omitted, performed in another or combined. Further, the method 100 may start after other steps in forming a magnetic memory have been performed.

A free layer is provided on the substrate, via step 102. In some embodiments, step 102 includes depositing the material(s) for the free layer. The free layer may be deposited on seed layer(s). The seed layer(s) may be selected for various purposes including but not limited to the desired crystal structure of the free layer, magnetic anisotropy and/or magnetic damping of the free layer. The edges of the magnetic junction, including those of the free layer, may be defined immediately after deposition or at a later time. For example, once the remaining layers of the magnetic junction have been deposited, the magnetic junction may be defined. In some embodiments, an ion mill may be performed. Thus, portions of step 102 may be spread out over time.

The free layer provided in step 102 is magnetic and thermally stable at operating temperatures. In some embodiments, the free layer provided in step is a multilayer. For example, the free layer maybe a synthetic antiferromagnet (SAF) and/or may include multiple adjoining ferromagnetic layers that are exchange or otherwise magnetically coupled. Further, in some embodiments, the perpendicular magnetic anisotropy energy of the free layer provided in step 102 exceeds the out-of-plane demagnetization energy. The magnetic moment of the free layer may thus be out-of-plane, including perpendicular-to-plane. In such embodiments, the free layer may include multilayers such as high interfacial anisotropy materials interleaved with coupling layers. In addition, a polarization enhancement layer (PEL) may be provided as part of or in addition to the free layer. A PEL includes high spin polarization materials. Materials deposited in step 102 may include Fe, Co, Ni, Ru, W and/or other material(s). For example, step 102 may include providing W/CoFeB bilayer(s), Ta/CoFeB bilayer(s), CoFeBAN/CoFeB trilayer(s). These multilayers may also be repeated. An insertion layer, such as Fe may also be provided in addition to or as part of the free layer. The free layer provided in step 102 is also configured to be switched between stable magnetic states when a write current is passed through the magnetic junction. Thus, the free layer is switchable utilizing spin transfer torque.

A nonmagnetic spacer layer is provided, via step 104. Step 104 may include depositing MgO, which forms a tunneling barrier layer. In some embodiments, step 104 may include depositing MgO using, for example, radio frequency (RF) sputtering. In other embodiments, metallic Mg may be deposited, then oxidized in step 104. As discussed above with respect to step 102, the edges of the nonmagnetic spacer layer may be defined at a later time, for example after deposition of the remaining layer of the magnetic junction.

The nonmagnetic spacer layer provided in step 104 may be amorphous as-deposited. However, the nonmagnetic spacer layer is desired to be crystalline. For example, crystalline MgO with a (100) orientation may be desired for enhanced tunneling magnetoresistance (TMR) of the magnetic junction. Consequently, the portion of the magnetic junction that has already been formed is annealed at a temperature of at least three hundred fifty degrees Celsius. Thus, at least the free layer formed in step 102 and the nonmagnetic spacer layer formed in step 104 are annealed, via step 106. In some embodiments, step 106 includes performing a rapid thermal anneal (RTA). In such an embodiments, the already-formed portion of the magnetic junction may be annealed for minutes or less. However, in other embodiments, the anneal may be performed in another manner, including but not limited to block heating. In some embodiments, the portion of the magnetic junction may be annealed in step 106 for at least 10 minutes and not more than ten hours. The anneal in step 106 may also be broken into multiple anneals. In such embodiments, the anneal times may differ. For example, a first anneal may be for less than ten minutes but at least one minute, while a second anneal may be at least ten minutes to hours long. Further, in some embodiments, higher anneal temperatures may be used. The anneal temperature may be desired not to exceed six hundred degrees Celsius. In some embodiments, the anneal is performed at a temperature of at least four hundred degrees Celsius. In some such embodiments, the anneal temperature is at least four hundred fifty degrees Celsius. The anneal temperature in some embodiments may be desired not to exceed five hundred degrees Celsius.

A pinned layer is provided after the annealing step, via step 108. As discussed above, portions of step 108 may be spaced apart in time. Thus, the nonmagnetic spacer layer is between the pinned layer and the free layer. The pinned layer is magnetic and may have its magnetization pinned, or fixed, in a particular direction during at least a portion of the operation of the magnetic junction. The pinned layer may thus be thermally stable at operating temperatures. The pinned layer formed in step 108 may be a simple (single) layer or may include multiple layers. For example, the pinned layer formed in step 108 may be a SAF including magnetic layers antiferromagnetically or ferromagnetically coupled through thin nonmagnetic layer(s), such as Ru. In such a SAF, each magnetic layer may also include multiple layers. The pinned layer may also be another multilayer. The pinned layer formed in step 108 may have a perpendicular anisotropy energy that exceeds the out-of-plane demagnetization energy. Thus, the pinned layer may have its magnetic moment oriented perpendicular to plane. Other orientations of the magnetization of the pinned layer are possible. In addition, it is noted that other layers, such as a PEL or coupling layer(s) may be inserted between the pinned layer and the nonmagnetic spacer layer.

Step 108 may include depositing magnetic material(s) such as Co, Ni, and Fe as well as nonmagnetic materials. As discussed above, the pinned layer provided in step 108 may be configured to have a high perpendicular anisotropy that exceeds the out-of plane. In such embodiments, Co/Pd multilayer(s), Co/Pt multilayer(s), CoPt alloys, Fe/Pt multilayer(s), Tb/CoFe multilayer(s), TbCo/Fe multilayer(s), TbCo/FeB multilayers, TbCoFe alloy(s), Co/Ni multilayer(s), CoFeB and/or other materials may be provided in step 108. In addition to avoiding the anneal performed in step 106, step 108 may deposit the materials, such as CoPt, at room temperature.

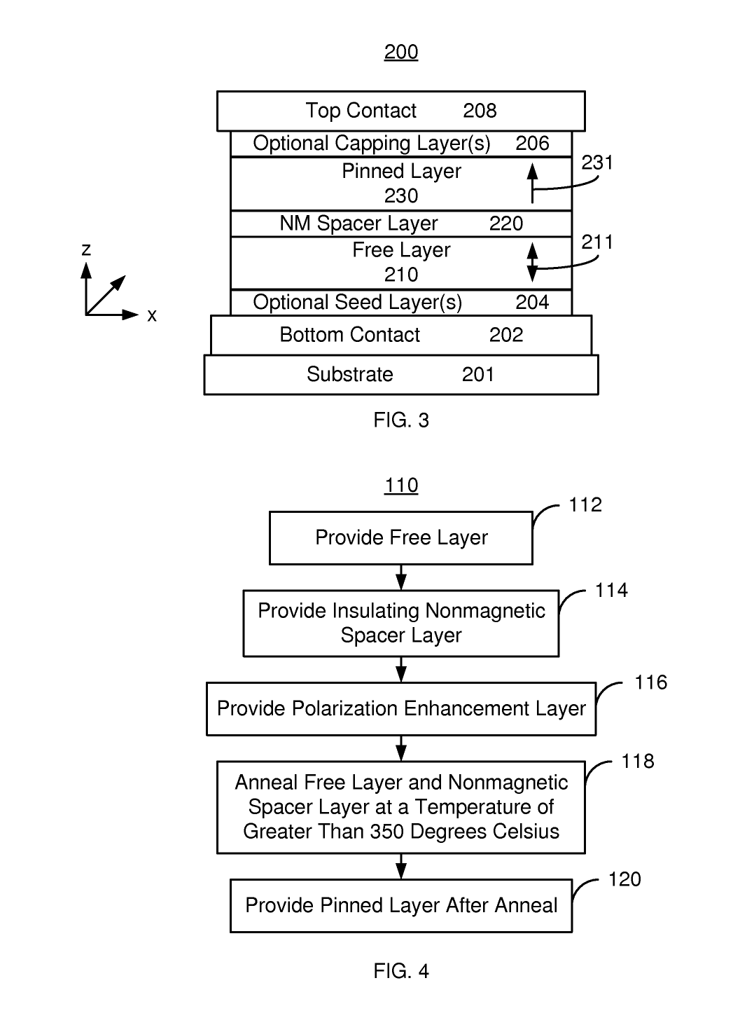

FIG. 3 depicts an exemplary embodiment of a magnetic junction 200 that may be fabricated using the method 100, as well as surrounding structures. For clarity, FIG. 3 is not to scale. The magnetic junction 200 may be used in a magnetic device such as a STT-RAM and, therefore, in a variety of electronic devices. The magnetic junction 200 includes a free layer 210 having magnetic moment 211, a nonmagnetic spacer layer 220, and a pinned layer 230 having magnetic moment 231. Also shown is an underlying substrate 201 in which devices including but not limited to a transistor may be formed. Bottom contact 202, top contact 208, optional seed layer(s) 204 and optional capping layer(s) 206 are also shown. As can be seen in FIG. 3, the pinned layer 230 is closer to the top (furthest from a substrate 201) of the magnetic junction 200. An optional pinning layer (not shown) may be used to fix the magnetization (not shown) of the pinned layer 230. In some embodiments, the optional pinning layer may be an AFM layer or multilayer that pins the magnetization (not shown) of the pinned layer 230 by an exchange-bias interaction. However, in other embodiments, the optional pinning layer may be omitted or another structure may be used.

The perpendicular magnetic anisotropy energies of the pinned layer 230 and of the free layer 210 each exceeds the out of plane demagnetization energies of the pinned layer 230 and free layer 210. Consequently, the magnetic moments 211 and 231 of the free layer 210 and the pinned layer 230, respectively, may be perpendicular to plane. The magnetic junction 200 is also configured to allow the free layer 210 to be switched between stable magnetic states when a write current is passed through the magnetic junction 200. Thus, the free layer 210 is switchable utilizing spin transfer torque.

The magnetic junction 200 and free layer 210 may have improved performance. Because an anneal was performed in step 106 before the pinned layer was provided in step 108, a higher anneal temperature may be used. As a result, the nonmagnetic spacer layer 220 may be better crystallized and have a texture more highly oriented in the desired direction. For example, an improved crystalline MgO nonmagnetic spacer layer 220 that has more of the film oriented in the 200. Consequently, a higher magnetoresistance may be achieved. In some embodiments, the TMR exceeds two hundred thirty percent. In some embodiments, the TMR may be at least two hundred fifty percent. This may be achieved without damaging the pinned layer 230 because the pinned layer 230 was not present during the anneal. If the anneal is performed after formation of the top pinned layer 230, the layer 230 may be damaged. Damage to the pinned layer 230 may result poorer performance such as a higher write current and/or a reduced TMR. The structure, composition and film quality of the pinned layer may also be improved. For example, unwanted lattice restructuring and compositional changes such as diffusion and the emergence of alternate phases may be reduced or avoided.

FIG. 4 depicts an exemplary embodiment of a method 110 for fabricating a magnetic junction usable in a magnetic device such as a STT-RAM and, therefore, in a variety of electronic devices. For simplicity, some steps may be omitted, performed in another or combined. Further, the method 110 may start after other steps in forming a magnetic memory have been performed.

A free layer is provided on the substrate, via step 112. Step 112 is analogous to the step 102 of the method 100. The free layer provided in step 112 is magnetic and thermally stable at operating temperatures. In some embodiments, the free layer provided in step is a multilayer. For example, the free layer maybe a SAF and/or may include multiple adjoining ferromagnetic layers that are exchange or otherwise magnetically coupled. Further, in some embodiments, the perpendicular magnetic anisotropy energy of the free layer provided in step 112 exceeds the out-of-plane demagnetization energy. The free layer may include multilayers such as high interfacial anisotropy materials interleaved with coupling layers. A PEL may be provided as part of or in addition to the free layer. Materials deposited in step 112 may include Fe, Co, Ni, Ru, W and/or other material(s). For example, step 112 may include providing W/CoFeB bilayer(s), Ta/CoFeB bilayer(s), CoFeB/W/CoFeB trilayer(s). These multilayers may also be repeated. An insertion layer, such as Fe may also be provided in addition to or as part of the free layer. The free layer provided in step 112 is also configured to be switched between stable magnetic states when a write current is passed through the magnetic junction. Thus, the free layer is switchable utilizing spin transfer torque.

A nonmagnetic spacer layer is provided, via step 114. Step 114 is analogous to step 104. Step 114 may include depositing MgO, which forms a tunneling barrier layer. Step 114 may include depositing MgO using, for example, RF sputtering, depositing and oxidizing metallic Mg and/or other methods.

A PEL is provided, via step 116. Step 116 may include depositing a high spin polarization material. As discussed above, the edges of the PEL may be defined at a later time, for example after deposition of the remaining layer of the magnetic junction. Step 116 may include depositing CoFeB, FeB, a Fe/CoFeB bilayer, half-metallic material(s) and/or Heusler alloy(s). For example, materials including but not limited to one or more of Co₂FeAl, Co₂FeAlSi, Co2MnSi, MnAl, and MnGa may be used for the PEL.

The nonmagnetic spacer layer provided in step 114 may be amorphous as-deposited. However, the nonmagnetic spacer layer is desired to be crystalline. For example, crystalline MgO with a (100) orientation may be desired to enhance TMR of the magnetic junction. Consequently, the portion of the magnetic junction that has already been formed is annealed at a temperature of at least three hundred fifty degrees Celsius, via step 118. Thus, at least the free layer formed in step 112, the nonmagnetic spacer layer formed in step 114 and the PEL formed in step 116 are annealed in step 118. Step 118 is analogous to step 106. Step 118 may include performing a RTA, using block heating and/or in another manner. In some embodiments, the portion of the magnetic junction may be annealed minutes or less. In some embodiments, the portion of the magnetic junction may be annealed in step 118 for at least 10 minutes and not more than ten hours. Further, in some embodiments, higher anneal temperatures may be used. The anneal temperature may be desired not to exceed six hundred degrees Celsius. In some embodiments, the anneal is performed at a temperature of at least four hundred degrees Celsius. In some such embodiments, the anneal temperature is at least for hundred fifty degrees Celsius. The anneal temperature in some embodiments may be desired not to exceed five hundred degrees Celsius.

A pinned layer is provided after the annealing step, via step 120. Step 120 is analogous to step 108. As discussed above, portions of step 120 may be spaced apart in time. Thus, the nonmagnetic spacer layer is between the pinned layer and the free layer. The PEL is between the nonmagnetic spacer layer and the pinned layer. The pinned layer is magnetic and may have its magnetization pinned, or fixed, in a particular direction during at least a portion of the operation of the magnetic junction. The pinned layer may thus be thermally stable at operating temperatures. The pinned layer formed in step 120 may be a simple (single) layer or may include multiple layers. For example, the pinned layer formed in step 120 may be a SAF, and/or may include other multilayers. In such embodiments, Co/Pd multilayer(s), Co/Pt multilayer(s), CoPt alloys, Fe/Pt multilayer(s), Tb/CoFe multilayer(s), TbCoFe alloy(s) Co/Ni multilayer(s), CoFeB and/or other materials may be provided in step 120. The pinned layer formed in step 120 may have a perpendicular anisotropy energy that exceeds the out-of-plane demagnetization energy. Thus, the pinned layer may have its magnetic moment oriented perpendicular to plane. Other orientations of the magnetization of the pinned layer are possible. In addition, it is noted that other layers, such as coupling layer(s) may be inserted between the pinned layer and the PEL. In some embodiments, the second pinned layer may be deposited at room temperature. For example, a CoPt alloy pinned layer may be deposited at room temperature for the second pinned layer in step 120 after the anneal(s) have been performed.

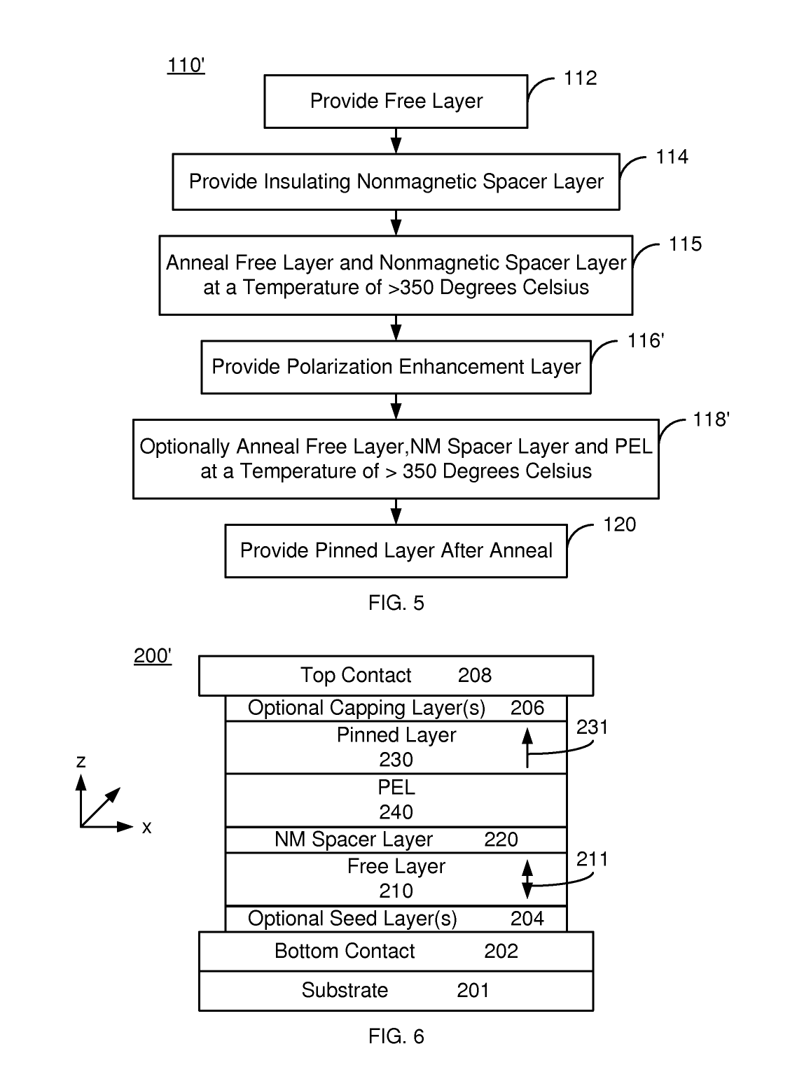

FIG. 5 depicts an exemplary embodiment of a method 110′ for fabricating a magnetic junction usable in a magnetic device such as a STT-RAM and, therefore, in a variety of electronic devices. For simplicity, some steps may be omitted, performed in another or combined. Further, the method 110′ may start after other steps in forming a magnetic memory have been performed. The method 110′ is analogous to the method 110. Consequently, analogous steps are labeled similarly.

A free layer is provided on the substrate, via step 112. Step 112 is analogous to the step 102 of the method 100 and step 112 of the method 110. A nonmagnetic spacer layer is provided, via step 114. Step 114 is analogous to step 104 and step 114 of the methods 100 and 110, respectively.

As discussed above, the nonmagnetic spacer layer provided in step 114 is desired to be annealed in order to improve the crystallization of material(s) such as MgO. Consequently, the portion of the magnetic junction that has already been formed is annealed at a temperature of at least three hundred fifty degrees Celsius, via step 115. The free layer and nonmagnetic spacer layer are thus annealed in step 115. In some embodiments, step 115 is the only anneal performed before deposition of the pinned layer, discussed below. However, in other embodiments, an additional anneal may be performed. Step 115 may include performing a RTA, using block heating and/or in another manner. In some embodiments, the portion of the magnetic junction may be annealed minutes or less. In some embodiments, the portion of the magnetic junction may be annealed in step 115 for at least 10 minutes and not more than ten hours. Further, in some embodiments, higher anneal temperatures may be used. The anneal temperature may be desired not to exceed six hundred degrees Celsius. In some embodiments, the anneal is performed at a temperature of at least four hundred degrees Celsius. In some such embodiments, the anneal temperature is at least four hundred fifty degrees Celsius. The anneal temperature in some embodiments may be desired not to exceed five hundred degrees Celsius. In embodiments in which multiple anneals are performed prior to deposition of the pinned layer, step 115 may be performed at lower temperatures, for example at least three hundred degrees Celsius, and for other times.

A PEL is provided, via step 116′. Step 116 is analogous to step 116 of the method 110. However, step 116′ is performed after step 115. The portion of the magnetic junction that has already been formed may optionally be annealed at a temperature of at least three hundred fifty degrees Celsius, via step 118′. Step 118′ may be analogous to step 118. In embodiments in which multiple anneals are carried out, however, step 118′ may be performed at lower temperatures and/or for different times. Thus, at least the free layer formed in step 112, the nonmagnetic spacer layer formed in step 114 and the PEL formed in step 116′ may be annealed in step 118′. Step 118′ may include performing a RTA, using block heating and/or in another manner. In some embodiments, the portion of the magnetic junction may be annealed minutes or less. In some embodiments, the portion of the magnetic junction may be annealed in step 118 for at least 10 minutes and not more than ten hours. Further, in some embodiments, higher anneal temperatures may be used. The anneal temperature may be desired not to exceed six hundred degrees Celsius. In some embodiments, the anneal is performed at a temperature of at least four hundred degrees Celsius. In some such embodiments, the anneal temperature is at least four hundred fifty degrees Celsius. The anneal temperature in some embodiments may be desired not to exceed five hundred degrees Celsius.

A pinned layer is provided after the annealing step, via step 120′. Step 120′ is analogous to step 108 and/or step 120. As discussed above, portions of step 120′ may be spaced apart in time. Thus, the nonmagnetic spacer layer is between the pinned layer and the free layer. The PEL is between the nonmagnetic spacer layer and the pinned layer.

FIG. 6 depicts an exemplary embodiment of a magnetic junction 200′ that may be fabricated using the method 110 or 110′, as well as surrounding structures. For clarity, FIG. 6 is not to scale. The magnetic junction 200′ may be used in a magnetic device such as a STT-RAM and, therefore, in a variety of electronic devices. The magnetic junction 200′ is analogous to the magnetic junction 200. Consequently, similar components have analogous labels. The magnetic junction 200′ includes a free layer 210 having magnetic moment 211, a nonmagnetic spacer layer 220, and a pinned layer 230 having magnetic moment 231 that are analogous to the free layer 210 having magnetic moment 211, the nonmagnetic spacer layer 220, and the pinned layer 230 having magnetic moment 231 depicted in the magnetic junction 200. Also shown is an underlying substrate 201, bottom contact 202, top contact 208, optional seed layer(s) 204 and optional capping layer(s) 206 that are analogous to the substrate 201, bottom contact 202, top contact 208, optional seed layer(s) 204 and optional capping layer(s) 206 for the magnetic junction 200. As can be seen in FIG. 6, the pinned layer 230 is closer to the top (furthest from a substrate 201) of the magnetic junction 200. An optional pinning layer (not shown) may be used to fix the magnetization (not shown) of the pinned layer 210. In some embodiments, the optional pinning layer may be an AFM layer or multilayer that pins the magnetization (not shown) of the pinned layer 110 by an exchange-bias interaction. However, in other embodiments, the optional pinning layer 106 may be omitted or another structure may be used.

Also depicted in FIG. 6 is PEL 240 that resides between the pinned layer 230 and the nonmagnetic spacer layer 220. For example, the PEL 240 may be a CoFeB alloy layer, a FeB alloy layer, a Fe/CoFeB bilayer, a half metallic layer or a Heusler alloy layer. Other high spin polarization materials may also be provided. In some embodiments, the PEL 240 is also configured to enhance the perpendicular magnetic anisotropy of the pinned layer 230.

The perpendicular magnetic anisotropy energies of the pinned layer 230 and of the free layer 210 each exceeds the out of plane demagnetization energies of the pinned layer 230 and free layer 210. Consequently, the magnetic moments 211 and 231 of the free layer 210 and the pinned layer 230, respectively, may be perpendicular to plane. The magnetic junction 200 is also configured to allow the free layer 210 to be switched between stable magnetic states when a write current is passed through the magnetic junction 200. Thus, the free layer 210 is switchable utilizing spin transfer torque.

The magnetic junction 200′ and free layer 210 may have improved performance. In particular, the magnetic junction 200′ may share the benefits of the magnetic junction 200. Because the anneal(s) are performed in step(s) 115 and 118′ before the pinned layer is provided in step 120, a higher anneal temperature may be used. As a result, a higher magnetoresistance may be achieved. In some embodiments, the TMR exceeds two hundred thirty percent. In some embodiments, the TMR may be at least two hundred fifty percent. This may be achieved without damaging the pinned layer 230 because the pinned layer 230 was not present during the anneal.

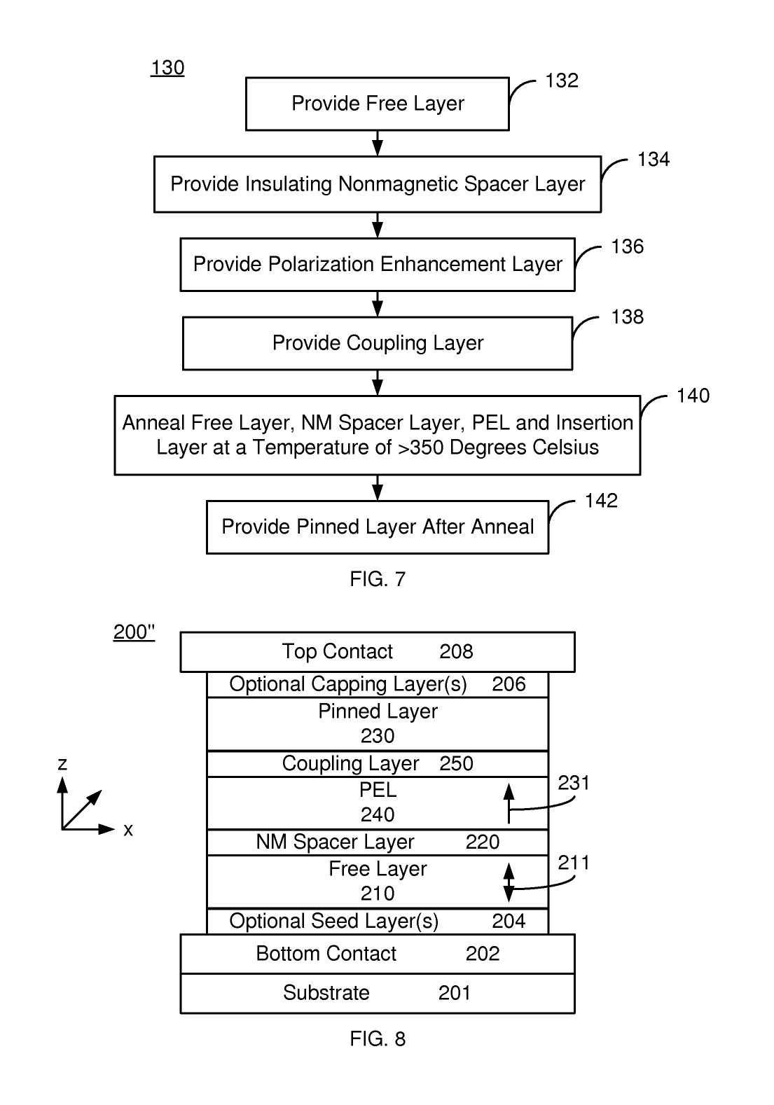

FIG. 7 depicts an exemplary embodiment of a method 130 for fabricating a magnetic junction usable in a magnetic device such as a STT-RAM and, therefore, in a variety of electronic devices. For simplicity, some steps may be omitted, performed in another or combined. Further, the method 130 may start after other steps in forming a magnetic memory have been performed.

A free layer is provided on the substrate, via step 132. Step 132 is analogous to step(s) 102 and 112 of the methods 100, 110, and 110′. The free layer provided in step 132 is magnetic and thermally stable at operating temperatures. In some embodiments, the free layer provided in step is a multilayer. Further, in some embodiments, the perpendicular magnetic anisotropy energy of the free layer provided in step 132 exceeds the out-of-plane demagnetization energy. The free layer may include multilayers such as high interfacial anisotropy materials interleaved with coupling layers. A PEL may be provided as part of or in addition to the free layer. An insertion layer, such as Fe may also be provided in addition to or as part of the free layer. The free layer provided in step 132 is also configured to be switched between stable magnetic states when a write current is passed through the magnetic junction. Thus, the free layer is switchable utilizing spin transfer torque.

A nonmagnetic spacer layer is provided, via step 134. Step 134 is analogous to step(s) 104 and 114 of the methods 100, 110 and/or 110′. Step 134 may include depositing MgO, which forms a tunneling barrier layer. Step 134 may be performed using, for example, RF sputtering, depositing and oxidizing metallic Mg and/or other methods.

A PEL is provided, via step 136. Step 136 is analogous to step 116 and/or 116′. A coupling layer is provided, via step 138. Step 138 includes providing a material through which the pinned layer, discussed below, may be coupled to the PEL. Step 138 may be performed over time. For example, the material(s) for the coupling layer may be deposited before formation of the pinned layer. At a later time, the edges of the coupling layer may be defined, for example via an ion mill.

Step 138 may include depositing one or more of HfB, Ta, W, Ti, Hf, a Fe/W bilayer, a W/Fe/W trilayer, a FeB/W bilayer, W/FeB/W trilayer, Ru, Cr, Ti, V and/or Mg. The thickness of the coupling layer provided in step 138 may be used to moderate the interaction between the PEL and the pinned layer.

The nonmagnetic spacer layer provided in step 134 may be amorphous as-deposited. However, the nonmagnetic spacer layer is desired to be crystalline. For example, crystalline MgO with a (100) orientation may be desired to enhance TMR of the magnetic junction. Consequently, the portion of the magnetic junction that has already been formed is annealed at a temperature of at least three hundred fifty degrees Celsius, via step 140. Thus, at least the free layer formed in step 132, the nonmagnetic spacer layer formed in step 134, the PEL formed in step 136 and the coupling layer formed in step 138 are annealed in step 140. In other embodiments, the anneal in step 140 may be performed at another time after deposition of the nonmagnetic spacer layer and before deposition of the pinned layer. Step 140 is analogous to step(s) 106, 118 and/or 118′. Step 140 may include performing a RTA, using block heating and/or in another manner. In some embodiments, the portion of the magnetic junction may be annealed minutes or less. In some embodiments, the portion of the magnetic junction may be annealed in step 140 for at least 10 minutes and not more than ten hours. Further, in some embodiments, higher anneal temperatures may be used. The anneal temperature may be desired not to exceed six hundred degrees Celsius. In some embodiments, the anneal is performed at a temperature of at least four hundred degrees Celsius. In some such embodiments, the anneal temperature is at least for hundred fifty degrees Celsius. The anneal temperature in some embodiments may be desired not to exceed five hundred degrees Celsius. In addition, step 140 may be spread into multiple anneals performed after deposition of the nonmagnetic spacer layer and before deposition of the pinned layer.

A pinned layer is provided after the annealing step, via step 142. Step 142 is analogous to step(s) 108, 120 and/or 120′. As discussed above, portions of step 142 may be spaced apart in time. Thus, the nonmagnetic spacer layer is between the pinned layer and the free layer. The PEL is between the nonmagnetic spacer layer and the coupling layer. The coupling layer may be between the PEL and the pinned layer. The pinned layer is magnetic and may have its magnetization pinned, or fixed, in a particular direction during at least a portion of the operation of the magnetic junction. The pinned layer may thus be thermally stable at operating temperatures. The pinned layer formed in step 142 may be a simple (single) layer or may include multiple layers. For example, the pinned layer formed in step 142 may be a SAF, and/or may include other multilayers. In such embodiments, Co/Pd multilayer(s), Co/Pt multilayer(s), CoPt alloys, Fe/Pt multilayer(s), Tb/CoFe multilayer(s), TbCo/Fe multilayer(s), TbCo/FeB multilayer(s), TbCoFe alloy(s) Co/Ni multilayer(s), CoFeB and/or other materials may be provided in step 142. The pinned layer formed in step 142 may have a perpendicular anisotropy energy that exceeds the out-of-plane demagnetization energy. Thus, the pinned layer may have its magnetic moment oriented perpendicular to plane. Other orientations of the magnetization of the pinned layer are possible. In addition, it is noted that other layers, such as coupling layer(s) may be inserted between the pinned layer and the PEL.

FIG. 8 depicts an exemplary embodiment of a magnetic junction 200″ that may be fabricated using the method 130, as well as surrounding structures. For clarity, FIG. 8 is not to scale. The magnetic junction 200′ may be used in a magnetic device such as a STT-RAM and, therefore, in a variety of electronic devices. The magnetic junction 200′ is analogous to the magnetic junction(s) 200 and/or 200′. Consequently, similar components have analogous labels. The magnetic junction 200 includes a free layer 210 having magnetic moment 211, a nonmagnetic spacer layer 220, a PEL 240 and a pinned layer 230 having magnetic moment 231 that are analogous to the free layer 210 having magnetic moment 211, the nonmagnetic spacer layer 220, the PEL 240 and the pinned layer 230 having magnetic moment 231 depicted in the magnetic junction 200. Also shown is an underlying substrate 201, bottom contact 202, top contact 208, optional seed layer(s) 204 and optional capping layer(s) 206 that are analogous to the substrate 201, bottom contact 202, top contact 208, optional seed layer(s) 204 and optional capping layer(s) 206 for the magnetic junction 200. As can be seen in FIG. 8, the pinned layer 230 is closer to the top (furthest from a substrate 201) of the magnetic junction 200. An optional pinning layer (not shown) may be used to fix the magnetization (not shown) of the pinned layer 210. In some embodiments, the optional pinning layer may be an AFM layer or multilayer that pins the magnetization (not shown) of the pinned layer 110 by an exchange-bias interaction. However, in other embodiments, the optional pinning layer 106 may be omitted or another structure may be used.

The perpendicular magnetic anisotropy energies of the pinned layer 230 and of the free layer 210 each exceeds the out of plane demagnetization energies of the pinned layer 230 and free layer 210. Consequently, the magnetic moments 211 and 231 of the free layer 210 and the pinned layer 230, respectively, may be perpendicular to plane. The magnetic junction 200 is also configured to allow the free layer 210 to be switched between stable magnetic states when a write current is passed through the magnetic junction 200. Thus, the free layer 210 is switchable utilizing spin transfer torque.

Also depicted in FIG. 8 is coupling layer 250 that resides between the pinned layer 230 and the PEL 240. For example, the coupling layer 250 may be a HfB alloy layer, a Ta layer, a W layer, a Ti layer, a Hf layer, a Fe/W bilayer, a W/Fe/W trilayer, a FeB/W bilayer, a W/FeB/W trilayer, a Ru layer, a Cr layer, a Ti layer, a V layer, and/or a Mg layer.

The magnetic junction 200″ may have improved performance. In particular, the magnetic junction 200″ may share the benefits of the magnetic junction 200 and/or 200′. Because the anneal(s) are performed in step(s) 140 before the pinned layer is provided in step 142, a higher anneal temperature may be used. As a result, a higher magnetoresistance may be achieved. In some embodiments, the TMR exceeds two hundred thirty percent. In some embodiments, the TMR may be at least two hundred fifty percent. This may be achieved without damaging the pinned layer 230 because the pinned layer 230 was not present during the anneal.

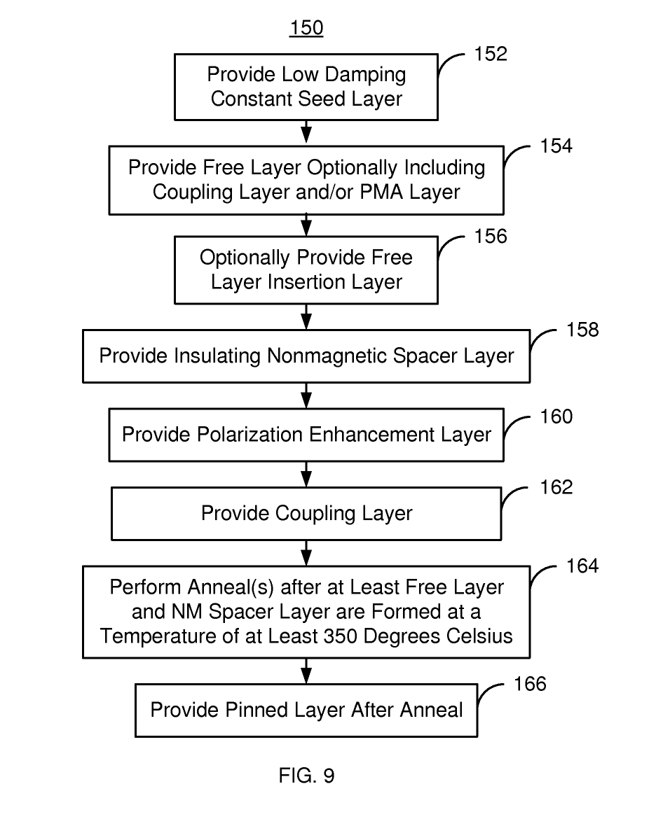

FIG. 9 depicts an exemplary embodiment of a method 150 for fabricating a magnetic junction usable in a magnetic device such as a STT-RAM and, therefore, in a variety of electronic devices. For simplicity, some steps may be omitted, performed in another or combined. Further, the method 150 may start after other steps in forming a magnetic memory have been performed. Portions of the method 150 are analogous to the method(s) 100, 110, 110′ and/or 130.

A seed layer is provided on the substrate, via step 152. Step 152 may be performed after formation of a bottom contact. In some embodiments, the seed layer is a low damping constant seed layer. In such embodiments, the seed layer is configured such that the free layer has a lower damping constant. A low damping constant may correspond to easier spin transfer based switching. Step 152 may, for example, include depositing one or more layers of tantalum oxide, AlN, AlTiN TiN, V, and/or aluminum oxide. In some embodiments, step 152 may include depositing a low resistance area (RA) MgO. A low RA MgO layer is one in which the RA is at least 0.1 and not more than 5. A low RA MgO layer may be provided by depositing an Mg layer, then naturally oxidizing at least a portion of the Mg layer. Such a natural oxide MgO layer may have a thickness of at least two Angstroms and not more than six Angstroms. A low RA MgO layer may also be formed by providing a thin RF-MgO layer. Such an RF-MgO layer may be at least four Angstroms thick and not more than eight Angstroms thick. In other embodiments, a hybrid MgO layer may be used. For example an RF-deposited MgO layer may be provided. An Mg layer may also be provided and oxidized. Such a hybrid MgO layer may have a thickness of at least four Angstroms and not more than ten Angstroms thick. Thus, the low RA layer is formed partially by an RF deposited MgO layer and partially by a naturally oxidized MgO layer. Step 152 might also be performed by providing a doped MgO layer.

A free layer is provided on the seed layer, via step 154. Step 154 is analogous to step(s) 102, 112 and/or 132 of the methods 100, 110, 110′ and/or 130. The free layer provided in step 154 is magnetic and thermally stable at operating temperatures. In some embodiments, the free layer provided in step is a multilayer. Further, in some embodiments, the perpendicular magnetic anisotropy energy of the free layer provided in step 154 exceeds the out-of-plane demagnetization energy. The free layer may include multilayers such as high interfacial anisotropy materials interleaved with coupling layers. A PEL may be provided as part of or in addition to the free layer. The free layer provided in step 132 is also configured to be switched between stable magnetic states when a write current is passed through the magnetic junction. Thus, the free layer is switchable utilizing spin transfer torque.

An insertion layer, such as Fe, may optionally be provided for the free layer, via step 156. Such an insertion layer may be used to reduce the RA of the junction being formed.

A nonmagnetic spacer layer is provided, via step 158. Step 158 is analogous to step(s) 104, 114 and/or 134 of the methods 100, 110, 110′ and/or 130. Step 156 may include depositing MgO, which forms a tunneling barrier layer. Step 156 may be performed using, for example, RF sputtering, depositing and oxidizing metallic Mg and/or other methods.

A PEL is provided, via step 160. Step 160 is analogous to step(s) 116, 116′ and/or 136. A coupling layer is provided, via step 162. Step 162 may be analogous to step 138. Step 162 includes providing a material through which the pinned layer, discussed below, may be coupled to the PEL.

The portion of the magnetic junction that has already been formed is annealed at a temperature of at least three hundred fifty degrees Celsius, via step 164. Step 164 may be analogous to step(s) 106, 115, 118, 118′, and/or step 140. The anneal in step 164 may be performed after deposition of the nonmagnetic spacer layer and before deposition of the pinned layer. Step 164 may also be broken into multiple anneals performed after deposition of the nonmagnetic spacer layer and before deposition of the pinned layer. Step 164 may include performing a RTA, using block heating and/or in another manner. In some embodiments, the portion of the magnetic junction may be annealed in step 164 for at least one hour and not more than ten hours. Further, in some embodiments, higher anneal temperatures may be used. The anneal temperature may be desired not to exceed six hundred degrees Celsius. In some embodiments, the anneal is performed at a temperature of at least four hundred degrees Celsius. In some such embodiments, the anneal temperature is at least four hundred fifty degrees Celsius. The anneal temperature in some embodiments may be desired not to exceed five hundred degrees Celsius.

A pinned layer is provided after the annealing step, via step 166. Step 166 is analogous to step(s) 108, 120, 120′ and/or 140. As discussed above, portions of step 166 may be spaced apart in time. Thus, the nonmagnetic spacer layer is between the pinned layer and the free layer. The PEL is between the nonmagnetic spacer layer and the coupling layer. The coupling layer may be between the PEL and the pinned layer. The pinned layer is magnetic and may have its magnetization pinned, or fixed, in a particular direction during at least a portion of the operation of the magnetic junction. The pinned layer may thus be thermally stable at operating temperatures. The pinned layer formed in step 166 may be a simple (single) layer or may include multiple layers. For example, the pinned layer formed in step 166 may be a SAF, and/or may include other multilayers. In such embodiments, Co/Pd multilayer(s), Co/Pt multilayer(s), CoPt alloys, Fe/Pt multilayer(s), Tb/CoFe multilayer(s), TbCoFe alloy(s) Co/Ni multilayer(s), CoFeB and/or other materials may be provided in step 166. The pinned layer formed in step 166 may have a perpendicular anisotropy energy that exceeds the out-of-plane demagnetization energy. Thus, the pinned layer may have its magnetic moment oriented perpendicular to plane. Other orientations of the magnetization of the pinned layer are possible. In addition, it is noted that other layers, such as coupling layer(s) may be inserted between the pinned layer and the PEL.

Fabrication of the magnetic junction may then be completed. For example, if steps 152-164 included deposition of the layers, then the layers may be masked and the magnetic junctions defined. Further, formation of other components for the device in which the magnetic junction is to be used may be completed.

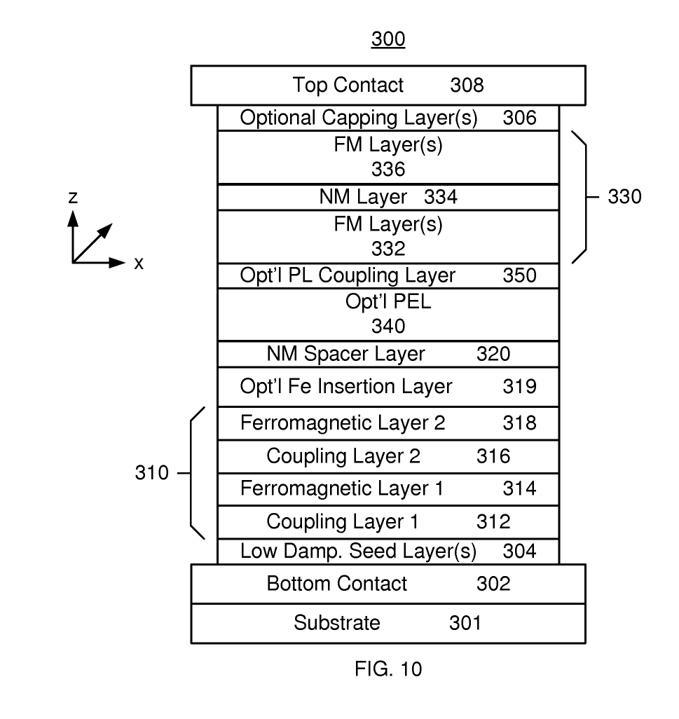

FIG. 10 depicts an exemplary embodiment of a magnetic junction 300 that may be fabricated using the method 150, as well as surrounding structures. For clarity, FIG. 10 is not to scale. The magnetic junction 300 may be used in a magnetic device such as a STT-RAM and, therefore, in a variety of electronic devices. The magnetic junction 300 is analogous to the magnetic junction(s) 200, 200′, and/or 200″. Consequently, similar components have analogous labels. The magnetic junction 300 includes a free layer 310, a nonmagnetic spacer layer 320, a PEL 340, a coupling layer 350 and a pinned layer 330 that are analogous to the free layer 210, the nonmagnetic spacer layer 220, the PEL 240, the coupling layer 250 and the pinned layer 230 depicted in the magnetic junctions 200, 200′, and 200″. Also shown is an underlying substrate 301, bottom contact 302, top contact 308, optional seed layer(s) 304 and optional capping layer(s) 306 that are analogous to the substrate 201, bottom contact 202, top contact 208, optional seed layer(s) 204 and optional capping layer(s) 206 for the magnetic junctions 200, 200′ and 200″. As can be seen in FIG. 10, the pinned layer 330 is closer to the top (furthest from a substrate 301) of the magnetic junction 300. An optional pinning layer (not shown) may be used to fix the magnetization (not shown) of the pinned layer 310.

The perpendicular magnetic anisotropy energies of the pinned layer 330 and of the free layer 310 may each exceed the out of plane demagnetization energies of the pinned layer 330 and free layer 310. Consequently, the magnetic moments of the free layer 310 and the pinned layer 330, respectively, may be perpendicular to plane. The magnetic junction 300 is also configured to allow the free layer 310 to be switched between stable magnetic states when a write current is passed through the magnetic junction 200. Thus, the free layer 310 is switchable utilizing spin transfer torque.

The seed layer 304 of the magnetic junction 300 may be a low damping seed layer, as discussed above. Also depicted in FIG. 10 is optional insertion layer 319 used for the free layer 310. Further, the free layer 310 includes layers 312 and 316 interleaved with ferromagnetic layers 314 and 316. The layer 316 is a coupling layer, while the layer 312 may be a seed layer. In some embodiments, the seed layer 312 includes a thin layer of W while in other embodiments, the seed layer 312 may be omitted. In some embodiments, the ferromagnetic layers 314 and 318 include material(s), such as CoFeB, that have a high interfacial perpendicular magnetic anisotropy. In some embodiments, the CoFeB layers 314 and 318 may include at least five and not more than ten Angstroms of CoFeB. The coupling layer 316 may be used to moderate the magnetic coupling between the ferromagnetic layers 314 and 318. Use of the layer 316 in connection with these high interfacial perpendicular magnetic anisotropy layers 314 and 318 may provide a free layer 310 having a perpendicular magnetic anisotropy and, therefore, a magnetic moment that is substantially perpendicular-to-plane. For example, the layer 312 may include approximately fifty Angstroms of W, while the coupling layer 316 may include at least two Angstroms and not more than three Angstroms of W. In some embodiments, the layer 312 may be omitted or replaced with a Ta layer.

In the embodiment shown in FIG. 10, the pinned layer 330 is a SAF including ferromagnetic layers 332 and 336 separated by nonmagnetic layer 334, which may be Ru. The ferromagnetic layer(s) 332 and 336 may each be a multilayer or may be a simple layer. Alternatively, the pinned layer 330 may be another multilayer or a simple layer.

The magnetic junction 300 may have improved performance. In particular, the magnetic junction 300 may share the benefits of the magnetic junction 200, 200′ and/or 200″. Because the anneal(s) are performed in step(s) 164 before the pinned layer is provided in step 166, a higher anneal temperature may be used. As a result, a higher magnetoresistance may be achieved without damaging the pinned layer. In addition, the free layer 310 may have reduced damping. The magnetic moments of the layers 310 and 330 may also be in the direction and have the magnitude desired. In some embodiments, therefore, the TMR exceeds two hundred thirty percent. In some embodiments, the TMR may be at least two hundred fifty percent.

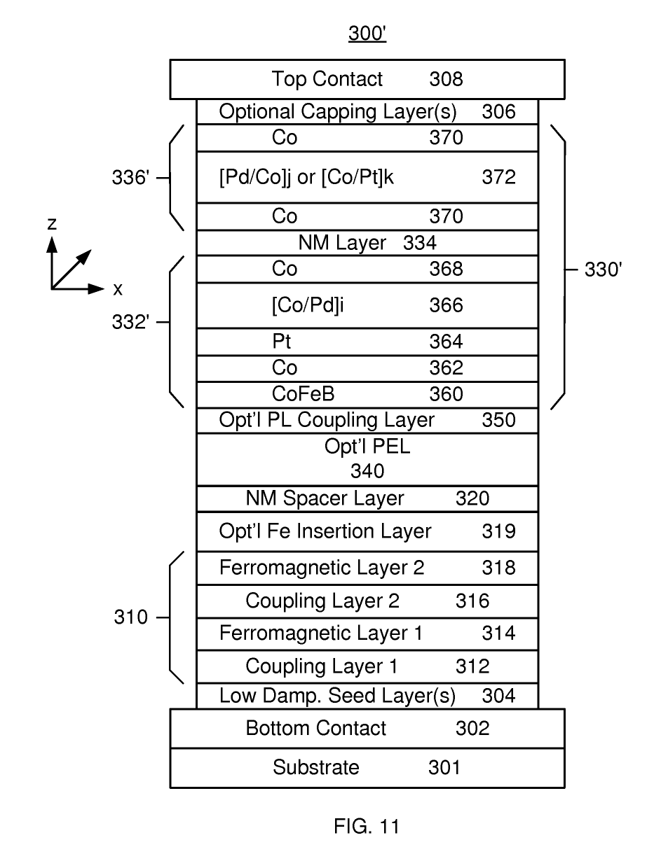

FIG. 11 depicts another exemplary embodiment of a magnetic junction 300′ that may be fabricated using the method 150, as well as surrounding structures. For clarity, FIG. 11 is not to scale. The magnetic junction 300′ may be used in a magnetic device such as a STT-RAM and, therefore, in a variety of electronic devices. The magnetic junction 300′ is analogous to the magnetic junction(s) 300, 200, 200′, and/or 200″. Consequently, similar components have analogous labels. The magnetic junction 300′ includes a free layer 310, a nonmagnetic spacer layer 320, a PEL 340, a coupling layer 350 and a pinned layer 330′ that are analogous to the free layer 210/310, the nonmagnetic spacer layer 220/320, the PEL 240/340, the coupling layer 250/350 and the pinned layer 230/330 depicted in the magnetic junctions 300, 200, 200′, and 200″. The free layer 310 includes layers 312, 314, 316 and 318 that are analogous to those for the magnetic junction 300. Also shown is an underlying substrate 301, bottom contact 302, top contact 308, optional low damping seed layer(s) 304 and optional capping layer(s) 306 that are analogous to the substrate 201/301, bottom contact 202/302, top contact 208/308, optional seed layer(s) 204/304 and optional capping layer(s) 206/306 for the magnetic junctions 200, 200′ and 200″. The pinned layer 330′ is closer to the top (furthest from a substrate 301) of the magnetic junction 300′. An optional pinning layer (not shown) may be used to fix the magnetization (not shown) of the pinned layer 310.

In the magnetic junction 300′, the pinned layer 330′ is a SAF including ferromagnetic layers 332′ and 336′ separated and magnetically coupled through nonmagnetic layer 334. The ferromagnetic layers 332′ and 336′ are each multilayers having a high perpendicular anisotropy. In particular, the magnetic layer 332′ includes a CoFeB layer 360 that may have a high spin polarization and may be four Angstroms thick, Co layer 362 that may be 3.5 Angstroms thick, Pt layer 364 that may be ten Angstroms thick, a Co/Pd bilayer 366 that is repeated i times and another Co layer 368 that may be five Angstroms thick. In some embodiments, i is four. In such embodiments, approximately 2.5 Angstroms of Co and ten Angstroms of Pd may be used. Similarly, the magnetic layer 336′ includes Co layer(s) 370 that may be five Angstroms thick and either a Co/Pd bilayer 372 having j repeats or a Co/Pt bilayer having k repeats. In some embodiments, j might be large, for example greater than twenty-eight. However, other thicknesses, repeats, and materials may be used in the layers 332′ and/or 336′. For example, alloys of CoPt and/or CoPd may be used in lieu of bilayers.

The magnetic junction 300′ may have improved performance. In particular, the magnetic junction 300′ may share the benefits of the magnetic junction 300, 200, 200′ and/or 200″. Because the anneal(s) are performed before the pinned layer is provided, a higher anneal temperature may be used. As a result, a higher magnetoresistance may be achieved without damaging the pinned layer. In addition, the free layer 310 may have reduced damping. The magnetic moments of the layers 310 and 330′ may also be in the direction and have the magnitude desired. In some embodiments, therefore, the TMR exceeds two hundred thirty percent. In some embodiments, the TMR may be at least two hundred fifty percent.

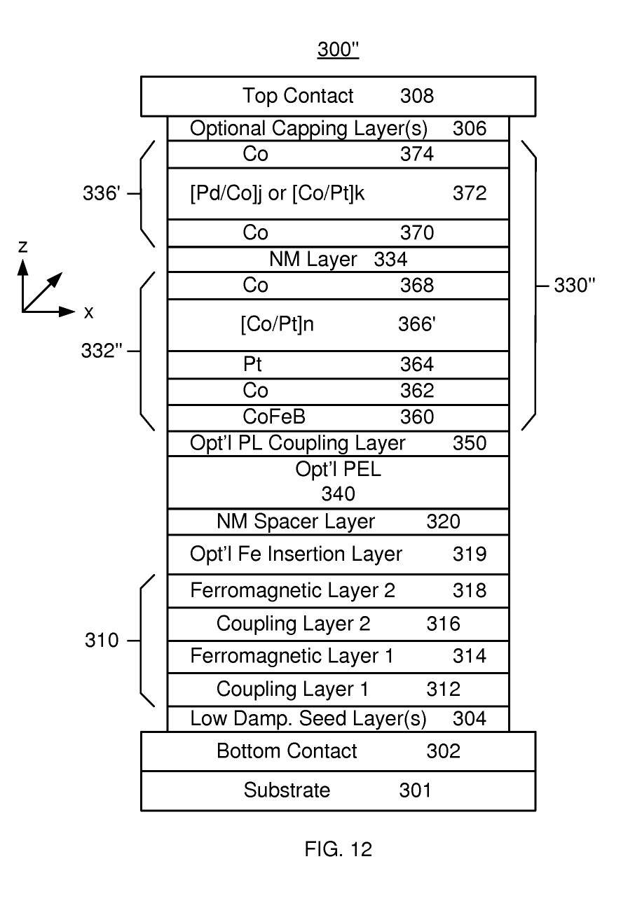

FIG. 12 depicts another exemplary embodiment of a magnetic junction 300″ that may be fabricated using the method 150, as well as surrounding structures. For clarity, FIG. 12 is not to scale. The magnetic junction 300″ may be used in a magnetic device such as a STT-RAM and, therefore, in a variety of electronic devices. The magnetic junction 300″ is analogous to the magnetic junction(s) 300, 300′, 200, 200′, and/or 200″. Consequently, similar components have analogous labels. The magnetic junction 300″ includes a free layer 310, a nonmagnetic spacer layer 320, a PEL 340, a coupling layer 350 and a pinned layer 330″ that are analogous to the free layer 210/310, the nonmagnetic spacer layer 220/320, the PEL 240/340, the coupling layer 250/350 and the pinned layer 230/330/330′ depicted in the magnetic junctions 300, 200, 200′, and 200″. The free layer 310 includes layers 312, 314, 316 and 318 that are analogous to those for the magnetic junction 300. Also shown is an underlying substrate 301, bottom contact 302, top contact 308, optional low damping seed layer(s) 304 and optional capping layer(s) 306 that are analogous to the substrate 201/301, bottom contact 202/302, top contact 208/308, optional seed layer(s) 204/304 and optional capping layer(s) 206/306 for the magnetic junctions 200, 200′ and 200″. The pinned layer 330″ is closer to the top (furthest from a substrate 301) of the magnetic junction 300″. An optional pinning layer (not shown) may be used to fix the magnetization (not shown) of the pinned layer 310.

In the magnetic junction 300″, the pinned layer 330″ is a SAF including ferromagnetic layers 332″ and 336′ separated and magnetically coupled through nonmagnetic layer 334. The ferromagnetic layers 332″ and 336′ are each multilayers having a high perpendicular anisotropy. In particular, the magnetic layer 332″ includes a CoFeB layer 360 that may have a high spin polarization and may be four Angstroms thick, Co layer 362 that may be 3.5 Angstroms thick, Pt layer 364 that may be ten Angstroms thick, a Co/Pt bilayer 366′ that is repeated n times and another Co layer 368 that may be five Angstroms thick. In some embodiments, n is four. In such embodiments, approximately three Angstroms of Co and eight Angstroms of Pt may be used. Similarly, the magnetic layer 336′ is a multilayer that is analogous to the layer 336′ discussed with respect to the magnetic junction 300′.

The magnetic junction 300″ may have improved performance. In particular, the magnetic junction 300″ may share the benefits of the magnetic junction 300, 300′, 200, 200′ and/or 200″. Because the anneal(s) are performed before the pinned layer is provided, a higher anneal temperature may be used. As a result, a higher magnetoresistance may be achieved without damaging the pinned layer. In addition, the free layer 310 may have reduced damping. The magnetic moments of the layers 310 and 330″ may also be in the direction and have the magnitude desired. Further, use of Pt in the layer 332″ may increase the coercivity of the pinned layer 330″. The pinned layer 330″ may thus be more magnetically stable. In some embodiments, the TMR exceeds two hundred thirty percent. In some embodiments, the TMR may be at least two hundred fifty percent.

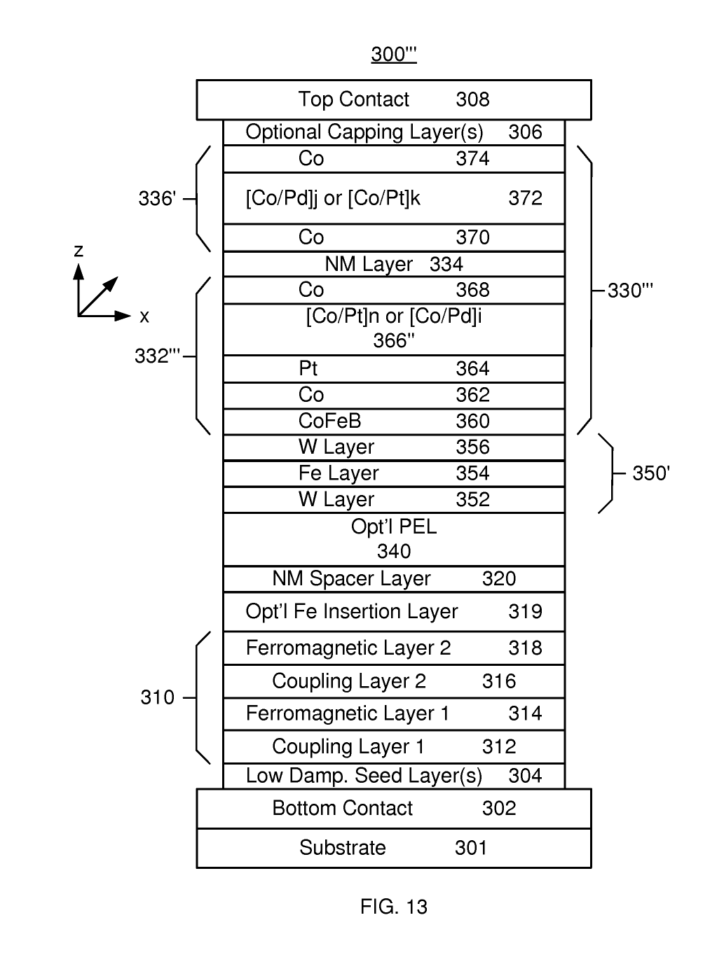

FIG. 13 depicts another exemplary embodiment of a magnetic junction 300′″ that may be fabricated using the method 150, as well as surrounding structures. For clarity, FIG. 13 is not to scale. The magnetic junction 300′″ may be used in a magnetic device such as a STT-RAM and, therefore, in a variety of electronic devices. The magnetic junction 300′″ is analogous to the magnetic junction(s) 300, 300′, 300″, 200, 200′, and/or 200″. Consequently, similar components have analogous labels. The magnetic junction 300″ includes a free layer 310, a nonmagnetic spacer layer 320, a PEL 340, a coupling layer 350′ and a pinned layer 330′″ that are analogous to the free layer 210/310, the nonmagnetic spacer layer 220/320, the PEL 240/340, the coupling layer 250/350 and the pinned layer 230/330/330′/330″ depicted in the magnetic junctions 300, 200, 200′, and 200″. The free layer 310 includes layers 312, 314, 316 and 318 that are analogous to those for the magnetic junction 300. Also shown is an underlying substrate 301, bottom contact 302, top contact 308, optional low damping seed layer(s) 304 and optional capping layer(s) 306 that are analogous to the substrate 201/301, bottom contact 202/302, top contact 208/308, optional seed layer(s) 204/304 and optional capping layer(s) 206/306 for the magnetic junctions 200, 200′ and 200″. The pinned layer 330″ is closer to the top (furthest from a substrate 301) of the magnetic junction 300″. An optional pinning layer (not shown) may be used to fix the magnetization (not shown) of the pinned layer 310.

The pinned layer 330′″ may be the pinned layer 330′ or 330″ depicted in FIG. 11 or 12, respectively. For example, either Co/Pd or Co/Pt may be used in the magnetic layer 332′″ and 336′. In addition, a particular embodiment of the coupling layer 350′ is shown. The coupling layer 350′ includes two W layers 352 and 356 sandwiching an Fe layer 354. In some embodiments, the W layers 352 and 356 may each be approximately two Angstroms thick. The Fe layer 354 may be approximately six Angstroms thick. However, other thicknesses may be used. Further, in other embodiments, other coupling layer(s) and/or other sublayers for the coupling layer may be used.

The magnetic junction 300′″ may have improved performance. In particular, the magnetic junction 300′″ may share the benefits of the magnetic junction 300, 300′, 300″, 200, 200′ and/or 200″. Because the anneal(s) are performed before the pinned layer is provided, a higher anneal temperature may be used. As a result, a higher magnetoresistance may be achieved without damaging the pinned layer. In addition, the free layer 310 may have reduced damping. The magnetic moments of the layers 310 and 330′″ may also be in the direction and have the magnitude desired. Further, use of Pt in the layer 332′″ may increase the coercivity of the pinned layer 330′″. The pinned layer 330′″ may thus be more magnetically stable. In some embodiments, the TMR exceeds two hundred thirty percent. In some embodiments, the TMR may be at least two hundred fifty percent.

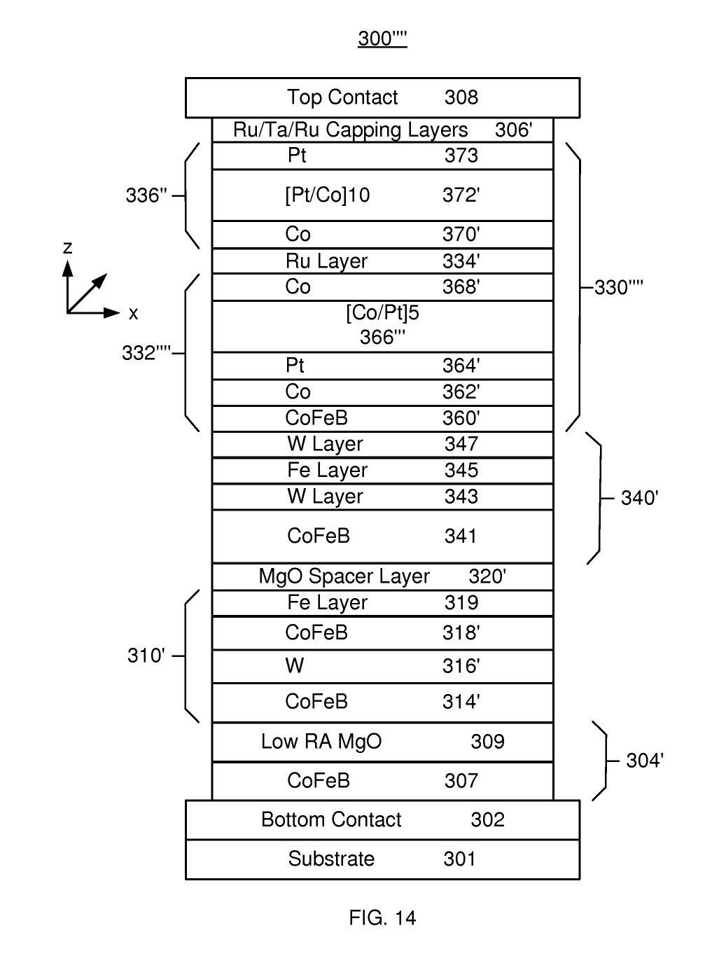

FIG. 14 depicts another exemplary embodiment of a magnetic junction 300′″ that may be fabricated using the method 150, as well as surrounding structures. For clarity, FIG. 14 is not to scale. The magnetic junction 300′″ may be used in a magnetic device such as a STT-RAM and, therefore, in a variety of electronic devices. The magnetic junction 300′″ is analogous to the magnetic junction(s) 300, 300′, 300″, 300′″, 200, 200′, and/or 200″. Consequently, similar components have analogous labels. The magnetic junction 300′″ includes a free layer 310′, a nonmagnetic spacer layer 320′, a PEL 340′ and a pinned layer 330′″ that are analogous to the free layer 210/310, the nonmagnetic spacer layer 220/320, the PEL 240/340 and the pinned layer 230/330/330′/330″/330′″ depicted in the magnetic junctions 300, 200, 200′, and 200″. The free layer 310 includes layers 314′, 316′ and 318′ that are analogous to those for the magnetic junction 300. Also shown is an underlying substrate 301, bottom contact 302, top contact 308, seed layer(s) 304′ and capping layer(s) 306′ that are analogous to the substrate 201/301, bottom contact 202/302, top contact 208/308, optional seed layer(s) 204/304 and optional capping layer(s) 206/306 for the magnetic junctions 200, 200′ and 200″. The pinned layer 330′″ is closer to the top (furthest from a substrate 301) of the magnetic junction 300″″. An optional pinning layer (not shown) may be used to fix the magnetization (not shown) of the pinned layer 330″″. Also shown are a CoFeB 307 and a low RA MgO layer 309 that form the seed layer 304′.

The magnetic junction 300″″ may be considered to be a specific implementation of the method 150 and the magnetic junction 300. The seed layer 304′ includes from closest to the substrate 301 to closest to the free layer 310′: ten Angstroms of Ta, five hundred Angstroms of Ir, ten Angstroms of Ta and twenty Angstroms of CoFeBTa (Ta/Ir/Ta/CoFeBTa). A bottom CoFeB layer 307 is also provided. The CoFeB layer 307 includes four Angstroms of CoFeB having twenty percent of B. A low RA MgO layer 309 that is formed by RF deposition is also included in the junction 300″″. In some embodiments, the deposition is performed for 625 seconds to provide the desired thickness and RA. For example, the low RA MgO layer may be approximately at least five Angstroms and not more than eight Angstroms thick. In other embodiments, other times and/or thicknesses may be used. The free layer 310′ is a multilayer. In the embodiment shown, the free layer is formed of a layer 314′ including six Angstroms of CoFeB having forty atomic percent Fe, a layer 316′ of two Angstroms of W, and a layer 318′ including nine Angstroms of CoFeB having twenty percent B and an additional layer 319 of four Angstroms of Fe. The nonmagnetic spacer layer 320′ is an MgO layer formed by RF deposition of MgO for 920 seconds. For example, the MgO layer 320′ may be approximately at least eight Angstroms and not more than ten Angstroms thick. In other embodiments, other times and/or thicknesses may be used. A first heat treatment is performed after formation of the MgO barrier layer 320′. In some embodiments, the heat treatment is an RTA. In some embodiments, the RTA is performed for not more than a few minutes and at a temperature of approximately 450 degrees Celsius. In some such embodiments, the anneal is for approximately ninety seconds. Thus, an anneal is performed after formation of the tunneling barrier 320′ but before formation of the PEL 340′ and pinned layer 330′″″. In other embodiments, other temperatures and/or times may be used.

The PEL 340′ includes a multilayer including four layers. These layers include a layer 342 of at least ten Angstroms and not more than sixteen Angstroms of CoFeB with twenty atomic percent B, a layer 343 of two Angstroms of W, a layer 345 of at least five Angstroms and not more than eight Angstroms of Fe and another layer 347 of two Angstroms of W. In some embodiments, the CoFeB layer 341 may be considered the PEL and the remaining layers 343, 345 and 347 may be considered to form a coupling layer analogous to the layer 350.

Another RTA at a temperature of 415 degrees Celsius is performed after formation of the PEL 340, but before formation of the pinned layer 330. Thus, for the magnetic junction 300″″, multiple anneals are performed between the tunneling barrier layer 320′ being deposited and the pinned layer 330″″ being deposited. In other embodiments, other temperatures and/or times may be used.

The pinned layer 330′″ is a SAF including two ferromagnetic multilayers 332″″ and 336″ separated by a Ru layer 334′ that is nine Angstroms thick in the embodiment shown. The first pinned layer 332″″ includes a four Angstrom layer 360′ of CoFeB having forty atomic percent B, a 3.5 Angstrom layer 362′ of Co, a ten Angstrom layer 364′ of Pt and five repeats of a bilayer 366″″ that includes three Angstroms of Co (the first of which adjoins the Pt layer 364′) and eight Angstroms of Pt. The multilayer 332″″ also includes another layer 368′ of Co that is five Angstroms thick. The second pinned layer 336″ includes a layer 370′ of five Angstroms of Co and ten repeats of a bilayer 372′ of eight Angstroms of Pt (the first of which adjoins the Co layer 370′) and three Angstroms 373 of Co. The second pinned layer 336″ also includes another layer 373 of eight Angstroms of Pt. The capping layer 306′ may be a multilayer that includes, from bottom (closest to the pinned layer 330″″) to top: fifteen Angstroms of Ru, fifteen Angstroms of Ta and another forty Angstroms of Ru adjoining the top contact. Note that the thicknesses described for the magnetic junction 300″″ may be approximate or as-measured. However, other thicknesses and other materials may be possible. Further, in other embodiments, other coupling layer(s) and/or other sublayers for the coupling layer may be used.

The magnetic junction 300″″ may have improved performance. In particular, the magnetic junction 300′″ may share the benefits of the magnetic junction 300, 300′, 300″, 300′″, 200, 200′ and/or 200″. Because the anneals are performed before the pinned layer is provided, a higher anneal temperature may be used. As a result, a higher magnetoresistance may be achieved without damaging the pinned layer. In addition, the free layer 310′ may have reduced damping. Analogous benefits may also be achieved for the pinned layer 330″″, the tunneling barrier layer, and remaining layers. In some embodiments, the TMR exceeds two hundred thirty percent.

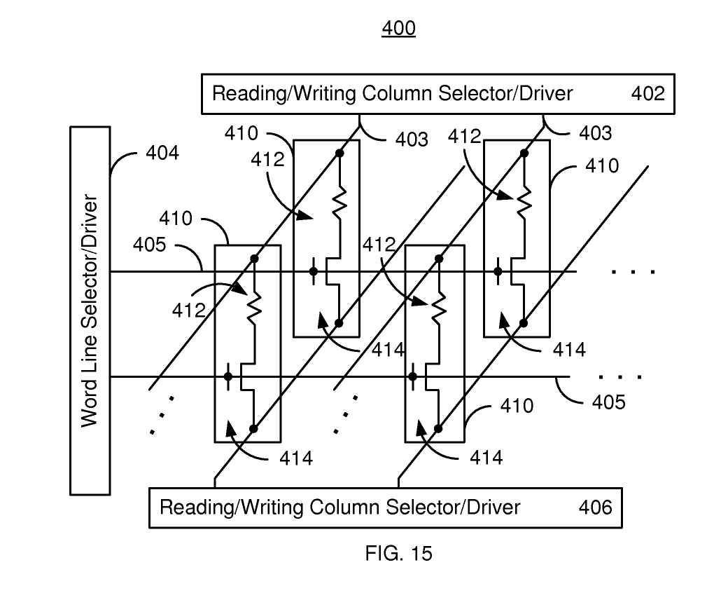

FIG. 15 depicts an exemplary embodiment of a memory 400 that may use one or more of the magnetic junctions 200, 200′, 200″, 300, 300′, 300″, 300′″ and/or 300″″. The magnetic memory 400 includes reading/writing column select drivers 402 and 406 as well as word line select driver 404. Note that other and/or different components may be provided. The storage region of the memory 400 includes magnetic storage cells 410. Each magnetic storage cell includes at least one magnetic junction 412 and at least one selection device 414. In some embodiments, the selection device 414 is a transistor. The magnetic junctions 412 may be one of the magnetic junctions 200, 200′, 200″, 300, 300′, 300″, 300′″ and/or 300″″ disclosed herein. Although one magnetic junction 412 is shown per cell 410, in other embodiments, another number of magnetic junctions 412 may be provided per cell. As such, the magnetic memory 400 may enjoy the benefits described above.

A method and system for providing a magnetic junction and a memory fabricated using the magnetic junction has been described. The method and system have been described in accordance with the exemplary embodiments shown, and one of ordinary skill in the art will readily recognize that there could be variations to the embodiments, and any variations would be within the spirit and scope of the method and system. Accordingly, many modifications may be made by one of ordinary skill in the art without departing from the spirit and scope of the appended claims.

We claim:

1. A method for providing a magnetic junction on a substrate usable in a magnetic device, the method comprising:
providing a free layer;
a nonmagnetic spacer layer;
annealing the free layer and the nonmagnetic spacer layer at an anneal temperature of at least three hundred fifty degrees Celsius; and
providing a pinned layer after the annealing step, the nonmagnetic spacer layer residing between the pinned layer and the free layer, the free layer being between the substrate and the pinned layer;
wherein the magnetic junction is configured such that the free layer is switchable between a plurality of stable magnetic states when a write current is passed through the magnetic junction.

2. The method of claim 1 wherein at least one of the free layer and the pinned layer has a perpendicular magnetic anisotropy energy greater than an out-of-plane demagnetization energy.

3. The method of claim 2 further comprising:
providing a polarization enhancement layer (PEL) between the pinned layer and the nonmagnetic spacer layer.

4. The method of claim 3 wherein the annealing step is performed after the step of providing the PEL.

5. The method of claim 3 wherein the annealing step is performed before the step of providing the PEL.

6. The method of claim 3 wherein the PEL includes at least one of CoFeB, FeB, a bilayer including a Fe layer and a CoFeB layer, a half metallic material and a Heusler alloy.

7. The method of claim 3 further comprising:
providing a coupling layer between the PEL and the pinned layer.

8. The method of claim 7 wherein the annealing step is performed after the step of providing the coupling layer.

9. The method of claim 5 further comprising:
performing an additional anneal at an additional anneal temperature of at least three hundred fifty degrees Celsius.

10. The method of claim 6 wherein the additional anneal temperature is at least four hundred degrees Celsius.

11. The method of claim 1 wherein the anneal temperature is at least four hundred fifty degrees Celsius.

12. The method of claim 1 wherein the anneal temperature is not more than six hundred degrees Celsius.

13. The method of claim 1 wherein the anneal temperature is not more than five hundred degrees Celsius

14. The method of claim 1 further comprising:
providing a seed layer, the seed layer including at least one of MgO, TiN and AlTiN.

15. The method of claim 10 wherein the free layer includes at least one insertion layer and at least one interfacial perpendicular magnetic anisotropy layer.

16. The method of claim 1 wherein the step of performing the anneal further includes performing a rapid thermal anneal.

17. The method of claim 1 wherein the step of providing the pinned layer further includes:
depositing at least one layer of CoPt substantially at room temperature.

18. A magnetic junction residing on a substrate and usable in a magnetic device comprising:
a free layer;
a nonmagnetic spacer layer;
and
a pinned layer, the nonmagnetic spacer layer residing between the pinned layer and the free layer, the free layer being closer to the substrate than the pinned layer, at least one of the free layer and the pinned layer having a perpendicular magnetic anisotropy energy greater than an out-of-plane demagnetization energy;
wherein the magnetic junction is configured such that the free layer is switchable between a plurality of stable magnetic states when a write current is passed through the magnetic junction; and
wherein the magnetic junction is configured to have a magnetoresistance of at least two hundred and fifty percent at twenty-five degrees Celsius.

19. The magnetic junction of claim 18 further comprising:
a seed layer between the free layer and the substrate, the seed layer including at least one of MgO, TiN and AlTiN;
a polarization enhancement layer (PEL) between the pinned layer and the nonmagnetic spacer layer, the PEL including at least one of CoFeB, FeB, a bilayer including a Fe layer and a CoFeB layer, a half metallic material and a Heusler alloy;
a coupling layer between the PEL and the pinned layer, the coupling layer including at least one of Fe and W; and
wherein the free layer includes at least one insertion layer and at least one interfacial perpendicular magnetic anisotropy layer.

20. A magnetic memory residing on a substrate, the magnetic memory comprising:
a plurality of magnetic storage cells, each of the plurality of magnetic storage cells including at least one magnetic junction, the at least one magnetic junction including a seed layer, a free layer, a nonmagnetic spacer layer, a polarization enhancement layer (PEL), a coupling layer and a pinned layer, the seed layer being between the free layer and the substrate, the seed layer including at least one of MgO, TiN and AlTiN, the free layer including at least one insertion layer and at least one interfacial perpendicular magnetic anisotropy layer, the nonmagnetic spacer layer being between the free layer and the pinned layer, the PEL being between the pinned layer and the nonmagnetic spacer layer, the PEL including at least one of CoFeB, FeB, a bilayer including a Fe layer and a CoFeB layer, a half metallic material and a Heusler alloy, the coupling layer being between the PEL and the pinned layer, the coupling layer including at least one of Fe and W, the free layer being closer to the substrate than the pinned layer, at least one of the free layer and the pinned layer having a perpendicular magnetic anisotropy energy greater than an out-of-plane demagnetization energy, the magnetic junction being configured such that the free layer is switchable between a plurality of stable magnetic states when a write current is passed through the magnetic junction, the magnetic junction being configured to have a magnetoresistance of at least two hundred and fifty percent at twenty-five degrees Celsius; and
a plurality of bit lines coupled with the plurality of magnetic storage cells.
